(19) United States
(12) Patent Application Publication
(10) Pub. No.: US 2014/0085839 A1
(43) Pub. Date: Mar. 27, 2014

(54) ELECTRONIC CONTROL DEVICE

(71) Applicant: Hitachi Automotive Systems, Ltd., Hitachinaka-shi (JP)

(72) Inventors: Kazuhiko NAKANO, Isesaki-shi (JP); Hirofumi WATANABE, Isesaki-shi (JP); Daisuke YASUKAWA, Hitachinaka-shi (JP); Toshio OTSUBO, Midori-shi (JP)

(73) Assignee: Hitachi Automotive Systems, Ltd., Hitachinaka-shi (JP)

(21) Appl. No.: 14/023,026

(22) Filed: Sep. 10, 2013

(30) Foreign Application Priority Data
Sep. 21, 2012 (JP) 2012-208814

(51) Int. Cl. H05K 5/00

(52) U.S. Cl. CPC H05K 5/0004
USPC 361/752

(57) ABSTRACT

An electronic control device has an enclosure accommodating therein a circuit board and having (a) a first enclosure member which is provided at a connecting part thereof with a seal groove and (b) a second enclosure member which is provided at a connecting part thereof with a convex line that is fitted into the seal groove of the first enclosure member; a protrusion formed on either one of an inner wall surface in the seal groove or an opposing surface, which faces the inner wall surface of the seal groove, of the convex line so as to protrude toward the other surface. The protrusion limits a movement, in a seal groove width direction, of the convex line fitted into the seal groove. The seal groove and the convex line are sealed with a sealant.

### BACKGROUND OF THE INVENTION

The present invention relates to an electronic control device having a circuit board that is accommodated in a protective space inside an enclosure of the electronic control device.

An electronic control device for generally used brake control unit, engine control unit and the like, mounted in a vehicle, has a structure in which a circuit board on which various electronic components (such as a processing unit and a semiconductor switching element) are mounted is accommodated in a protective space (a waterproof space) inside an enclosure that is formed by connecting a plurality of enclosure members together. For instance, regarding two of the plurality of enclosure members, which are arranged so as to face each other and are connected to each other, one enclosure member is provided at a connecting part thereof with a seal groove, while the other enclosure member is provided at a connecting part thereof with a convex line that can be fitted into the seal groove. Then, a sealing material is provided between these seal groove and convex line (for example, the seal groove is filled with the sealing material) and the convex line is inserted and fitted into the seal groove through the sealing material. Such structure that the seal groove and the convex line are liquid-tightly sealed and connected together by the sealing material is disclosed in e.g. Japanese Patent Provisional Publication No. 2012-070508 (hereinafter is referred to as “JP2012-070508”).

### SUMMARY OF THE INVENTION

In JP2012-070508, however, upon connecting the one enclosure member and the other enclosure member together in an assembly process, a positioning operation of the convex line of the other enclosure member with respect to the seal groove of the one enclosure member, to be positioned at a predetermined position in the seal groove, is needed before connecting these enclosure members. Further, even if this positioning to the predetermined position is achieved, since there is some gap between the seal groove and the convex line (e.g. a gap that is formed in order to be easily filled with the sealing material), the convex line of the other enclosure member tends to shift from the predetermined position in the seal groove of the one enclosure member. Because of this positioning shift, workability of the assembly could be deteriorated.

It is therefore an object of the present invention to provide an electronic control device that is capable of suppressing the positioning shift between the connecting enclosure members.

According to one aspect of the present invention, an electronic control device having a circuit board on which electronic components are mounted, the electronic control device comprises: an enclosure formed from a plurality of enclosure members and accommodating the circuit board in a space inside the enclosure, the enclosure having (a) a first enclosure member which is provided at a connecting part thereof with a seal groove; and (b) a second enclosure member which is provided at a connecting part thereof with a convex line that is fitted into the seal groove of the first enclosure member, and the first and second enclosure members being connected together to form the enclosure; and a protrusion formed on either one of an inner wall surface in the seal groove or an opposing surface, which faces the inner wall surface of the seal groove, of the convex line so as to protrude toward the other surface, the protrusion limiting a movement, in a seal groove width direction, of the convex line fitted into the seal groove, and the seal groove and the convex line is sealed with a sealant.

According to the present invention, the convex line of the second enclosure member can be inserted and fitted into the seal groove of the first enclosure member while the movement of the convex line in the seal groove width direction being limited by the protrusion. It is therefore possible to suppress the positioning shift of the first and second enclosure members and improving the workability of the assembly.

The other objects and features of this invention will become understood from the following description with reference to the accompanying drawings.

### BRIEF DESCRIPTION OF THE DRAWINGS

FIG. 1 is a perspective exploded view, viewed from a lower side, of an actuator unit having, as an example, an electronic control device of the present embodiments.

FIG. 2 is a perspective exploded view, viewed from an upper side, of the actuator unit of FIG. 1.

FIG. 3 is a perspective exploded view of the electronic control device of FIG. 2.

FIG. 4 is a sectional view of the electronic control device, cut along a line A-A of FIG. 2.

FIG. 5 is a perspective view of a case, as a unit, of FIG. 3

FIG. 6 is a sectional view for explaining a protrusion according to an embodiment 1.

FIG. 7 is a perspective view for explaining a protrusion according to an embodiment 2.

FIG. 8 is a sectional view for explaining a protrusion according to an embodiment 3.

FIG. 9 is a sectional view for explaining a protrusion according to an embodiment 4.

FIG. 10 is a sectional view for explaining a protrusion according to an embodiment 5.

FIG. 11 is a sectional view for explaining a protrusion according to an embodiment 6.

FIG. 12 is a sectional view for explaining a protrusion according to an embodiment 7 (a perspective view, viewed from a back side of a cover).

FIG. 13 is a sectional view for explaining a protrusion according to the embodiment 7 (a perspective view, viewed from the back side of the cover).

### DETAILED DESCRIPTION OF THE INVENTION

Embodiments of an electronic control device of the present invention will now be explained below with reference to the drawings.

An electronic control device according to the embodiments of the present invention is a device that has a structure in which a circuit board on which electronic components are mounted is accommodated in a space inside an enclosure that is formed by connecting a plurality of enclosure members together.

More specifically, the enclosure of the electronic control device has a first enclosure member that is provided at a connecting part thereof with a seal groove and a second enclosure member that is provided at a connecting part thereof with a convex line that can be fitted into the seal groove of the first enclosure member. Further, a protrusion is formed on either one of an inner wall surface in the seal groove or a surface (hereinafter called an opposing surface), which faces the inner wall surface of the seal groove, of the convex line. That is, the protrusion is formed on either one of the inner wall surface of the seal groove or the opposing surface of the convex line, and protrudes toward the other surface. The protrusion has such shape and serves to restrain or limit a movement, in a seal groove width direction, of the convex line when fitting the convex line into the seal groove for the positioning of the first and second enclosure members.

By forming the protrusion, when the first and second enclosure members are connected together, the convex line is fitted into the seal groove while being guided to a predetermined position in the seal groove with the movement of the convex line in the seal groove width direction limited by the protrusion. That is, the positioning shift between the first and second enclosure members upon the connection is suppressed, the assembly is thus facilitated.

If the positioning shift is not suppressed, for instance, fixing (fixing with a screw) of the first and second enclosure members at a certain position could be hindered. Further, in a case where the convex line is fitted into the seal groove with a sealing material (a sealant) provided between the seal groove and the convex line (e.g. the seal groove is filled with the sealing material), the sealing material is scraped away by the shifted convex line, and consequently sealing performance might be decreased.

With respect to the protrusion, it is formed on either one of the inner wall surface of the seal groove or the opposing surface of the convex line so as to merely protrude from either one of the inner wall surface or the opposing surface toward the other surface. As compared with, for instance, a positioning structure (a fixing convex line 39, a fixing portion 41 etc.) of JP2012-070508, the protrusion of the present invention has a simple shape, and can be readily formed.

This protrusion is formed on either one of the inner wall surface of the seal groove or the opposing surface of the convex line, as described above. However, with regard to a portion where the protrusion is formed, a filling amount of the sealing material at this protrusion forming portion tends to be small and also a creepage distance of the sealing material at this protrusion forming portion becomes short, as compared with a section except the protrusion forming portion.

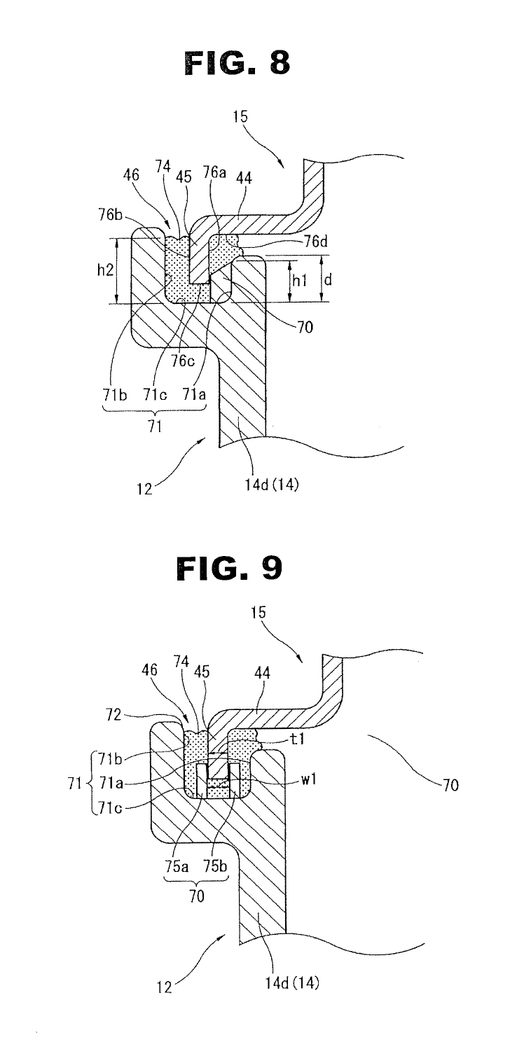

As an example, this will be explained using an after-mentioned FIG. 8. In FIG. 8, since a section except a portion where a protrusion 70 is formed is sufficiently filled with the sealing material, a shortest distance along an inner wall surface 71 (an outer circumferential surface 71b, a bottom wall surface 71c and an inner circumferential surface 71a, in a case where the protrusion 70 is removed in FIG. 8) of a seal groove 46 is the creepage distance. And also, a shortest distance along a fitting surface (an opposing surface 76b, a top end surface 76c, an opposing surface 76a and a bending surface 76d, in the case where the protrusion 70 is removed in FIG. 8) between a convex line (a protruding edge in the embodiments) 45 and the seal groove 46 is the creepage distance.

On the other hand, as for the portion where the protrusion 70 is formed, a shortest distance along a surface up to the protrusion 70 on the inner wall surface 71 (i.e. along the outer circumferential surface 71b and a part of the bottom wall surface 71c in FIG. 8) in the seal groove 46 is the creepage distance. And also, a shortest distance along a surface up to the protrusion 70 on the fitting surface (i.e. along the opposing surface 76b and the top end surface 76c in FIG. 8) between the convex line 45 and the seal groove 46 is the creepage distance. As is understood from the above explanation, the creepage distance of the portion where the protrusion 70 is formed is short as compared with the creepage distance of the section except the protrusion 70 forming portion.

In such cases, rather than creating a fitting structure so that an enclosure inner side of the protrusion can be filled with the sealing material, it is preferable to create a fitting structure so that an enclosure outer circumferential side of the protrusion can be filled with more sufficient sealing material and increase the sealing performance at the enclosure outer circumferential side of the protrusion. For example, the protrusion is formed at an inner circumferential surface side, which is located at the inner side of the enclosure, on the inner wall surface in the seal groove. Or alternatively, the protrusion is formed on the opposing surface, which faces the inner circumferential surface side of the seal groove, of the convex line. With this structure, the filling amount of the sealing material at the enclosure outer circumferential side of the protrusion forming portion can be sufficiently secured with ease, thereby suppressing the decrease of the sealing performance.

Further, according to this structure, since a gap between the convex line and an outer circumferential surface side, which is located at an outer side of the enclosure, on the inner wall surface in the seal groove is filled with the sealing material, these seal groove and convex line are not exposed to the outside air etc. of the enclosure, and protection against corrosion can be enhanced.

In addition, a plurality of protrusions could be separately arranged so as to be interspersed with the protrusions spaced apart from each other. For instance, it is conceivable that, in a case where the first enclosure member has a four-side-surrounding circumferential wall and the seal groove is formed at a top edge of the circumferential wall, not only the protrusion will be provided at each seal groove or each convex line which are placed at the four sides, but also a part of the one side seal groove (or of the one side convex line) of the four sides will have a shape extending straight and the number of protrusion provided at this straight part of the one side seal groove (or of the one side convex line) will be set to two or more. With this structure, even when the first enclosure member and the second enclosure member relatively rotate with respect to an extending direction of the seal groove and the positioning shift occurs, by the two protrusions or more provided at the straight part of the one side seal groove (or the one side convex line), the rotation to movement is limited and the positioning shift is suppressed.

The shape of the protrusion can be changed as long as the movement, in the seal groove width direction, of the convex line can be limited by the protrusion. For instance, in the case where the protrusion is formed on the inner wall surface of the seal groove, the protrusion is not formed into such shape that the protrusion merely extends from a bottom wall surface side to an opening side of the inner wall surface, but the protrusion is formed into such shape that the protrusion has a tapered surface that tilts or slopes in an oblique upward direction from the bottom wall surface side toward the opening side, e.g. such shape that a size (a length) of the protrusion in a seal groove extending direction becomes shorter from the bottom wall surface side toward the opening side (namely that the protrusion is shaped into a substantially pyramidal shape that tapers from the bottom wall surface side toward the opening side).

By employing the protrusion having such tapered surface, for instance, in a case where a liquid sealing material such as a liquid gasket (e.g. thermosetting FIPG formed from silicon etc.) is provided around the protrusion in the seal groove, a root portion of the protrusion (a boundary portion between the bottom wall surface and the protrusion) can also be easily filled with the sealing material without any void, then an occurrence of air bubbles in the sealing material can be suppressed.

Additionally, with respect to a size of the protrusion in a seal groove depth direction, it could be set to be not only smaller than a depth of the seal groove, but also smaller than a filling height of the sealing material. With this setting, the protrusion is buried in the sealing material and the creepage distance of the sealing material (a distance of the fitting surface between the seal groove and the convex line) can be adequately secured, thereby getting intended or desired sealing performance.

Shape and material of each of the first and second enclosure members are not especially limited as long as these first and second enclosure members are connected together to form the enclosure and the enclosure can accommodate therein the circuit board. As the material of the first and second enclosure members, various materials having heat dissipation (heat radiation) nature, noise resistance and durability (heat resistance, weather resistance and strength) can be selected depending on a target use environment of the electronic control device. For example, as will be described later, a metal or resin case (the first enclosure member) and a metal or resin cover (the second enclosure member) can be used.

Also regarding material of the sealing material (the sealant), it is not especially limited as long as the sealing material can seal both of the seal groove and the convex line with the sealing material provided between these seal groove and convex line. As the material of the sealing material, various materials having sealing performance, adhesiveness and durability (protection against corrosion, heat resistance, weather resistance and permanent compressive distortion or strain resistance) can be selected depending on the target use environment of the electronic control device. For example, various gaskets (such as FIPG (Formed In Place Gasket) and CIPG (Cured In Place Gasket)) and an adhesive can be used.

As a manner of forming the protrusion at the first enclosure member and the second enclosure member, it is not especially limited as long as the protrusion can be formed at a predetermined position of the first and second enclosure members. For example, various forming such as molding, pressing, sheet-metal working can be used.

<Configuration of Electronic Control Device>

In the following description, the electronic control device of the present embodiments, which is applied to an actuator unit of a vehicle, will be explained below with reference to the drawings.

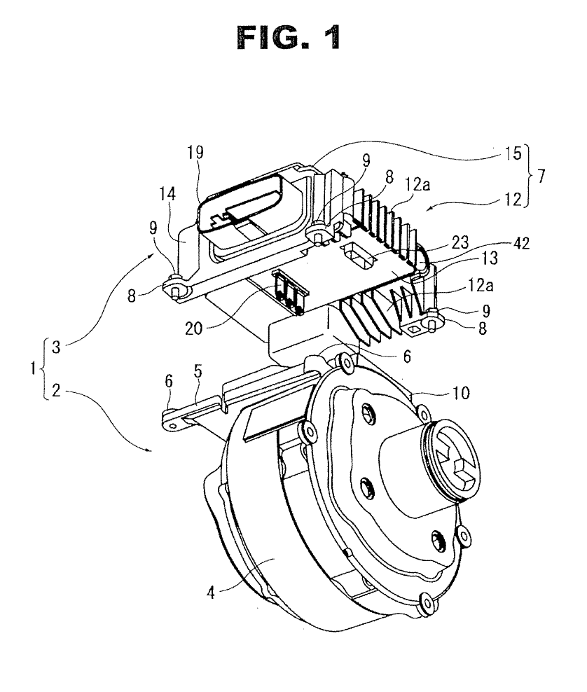

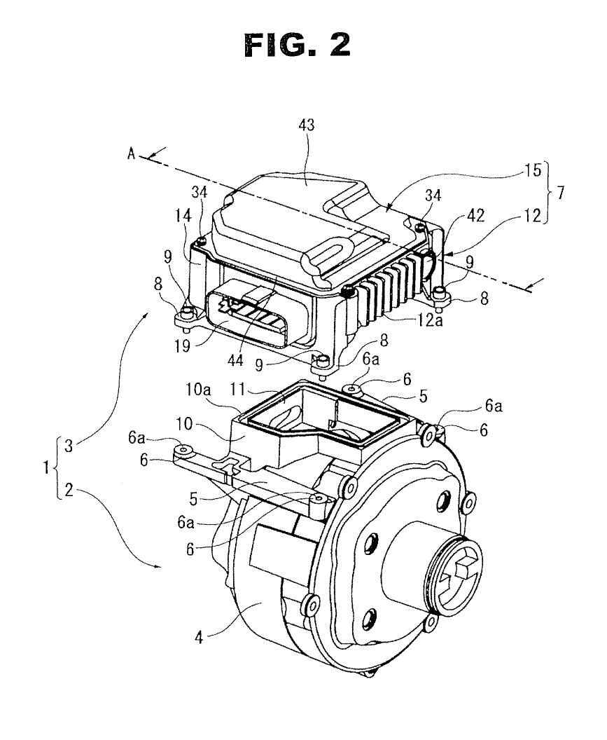

An actuator unit 1 shown in FIGS. 1 and 2 is a unit that is used for an electric brake boost apparatus mounted in the vehicle. The actuator unit 1 has an electric motor 2 that is an electric actuator driven by three-phase AC power and controlling a hydraulic pressure of brake fluid and a motor control device (an electronic control device) 3 that controls drive of the electric motor 2 on the basis of driver's braking operation and an operating condition of the vehicle. Although there is no drawing, the electric motor 2 controls, by a so-called ball screw mechanism, forward/backward movement of a piston (not shown) that controls the hydraulic pressure of the brake fluid.

The electric motor 2 is housed in a cylindrical motor housing 4. As can be seen in FIG. 2, a pair of seating portions 5 extending in an axial direction of the electric motor 2 are provided with the seating portions 5 spaced apart from each other at a predetermined distance in a direction perpendicular to the axial direction of the electric motor 2. Both ends, in a longitudinal direction, of each seating portion 5 are provided with a circular seating surface 6 that protrudes and has a screw hole 6a. On the other hand, a case 12 (described later) of an enclosure 7 of the motor control device 3 is provided with four leg portions 8 that are seated on the respective seating surfaces 6 of the motor housing 4. Then the motor control device 3 is fixed to the electric motor 2 with four control device fixing screws 9 that are inserted into the respective leg portions 8 of the enclosure 7 (the case 12) and are screwed into the respective screw holes 6a of the motor housing 4.

Between both of the seating portions 5 of the motor housing 4, a substantially rectangular tubular wall 10 is formed so as to protrude toward the enclosure 7. More specifically, the tubular wall 10 is formed so that when the enclosure 7 of the motor control device 3 is fixed to the motor housing 4, a stator connector 20 and a sensor connector 23, provided on a motor control device 3 side, face an inside of the motor housing 4 through an opening 11 that opens at an inner circumferential side of the tubular wall 10.

The stator connector 20 has a terminal that is connected to a stator (not shown) provided inside the motor housing 4. The sensor connector 23 has a structure in which connectors such as a rotation position sensor connector and a temperature sensor connector are united. The rotation position sensor connector is connected to a harness (not shown) that connects to a rotation position sensor in the motor housing 4. The temperature sensor connector is connected to a harness (not shown) that connects to a temperature sensor in the motor housing 4. Here, as is well known, the rotation position sensor is a sensor to detect a rotation position of a rotor (not shown) provided in the motor housing 4. An output signal of the rotation position sensor is used for the drive control of the electric motor 2 by the motor control device 3. The temperature sensor is a sensor to detect an operating temperature of the electric motor 2, more specifically, a coil temperature of the electric motor 2.

The tubular wall 10 enclosing the opening 11 is provided at a top end thereof with a seamlessly continuous groove portion 10a. A sealing member (not shown) is provided and arranged at this groove portion 10a, then seals the motor housing 4 when a bottom wall 13 of the case 12 is pressure-welded to the tubular wall 10 and the sealing member is pressed between them.

As shown in FIGS. 1 to 3, the enclosure 7 of the motor control device 3 is formed from the case 12 (the first enclosure member) and the a cover 15 (the second enclosure member). The case 12 has the bottom wall 13 and a four-side-surrounding circumferential wall 14. The case 12 has a substantially rectangular shape when viewed from above, and an upper side of the case 12 opens upward.

The cover 15 has a substantially rectangular shape when viewed from above, and covers the upper side opening of the case 12.

The enclosure 7 accommodates therein a power module 16 that corresponds to the circuit board and a control module 17 that corresponds to a second circuit board. More specifically, the power module 16 is located on a bottom wall 13 side of the case 12, and the control module 17 is located above the power module 16 with the both modules 16 and 17 arranged in layer and spaced by a certain distance. The enclosure 7 is fixed to the motor housing 4 with the bottom wall 13 of the case 12 facing a motor housing 4 side.

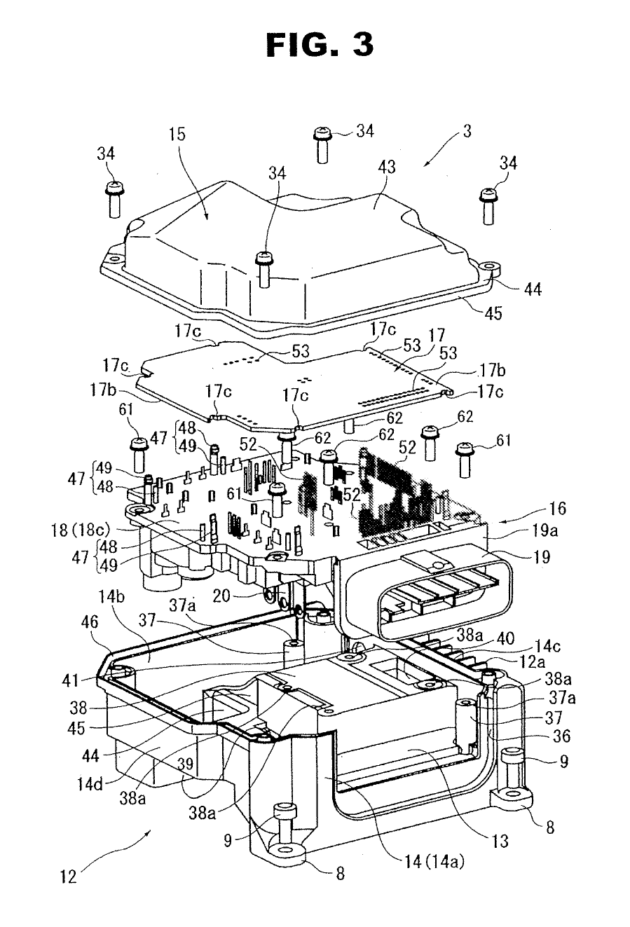

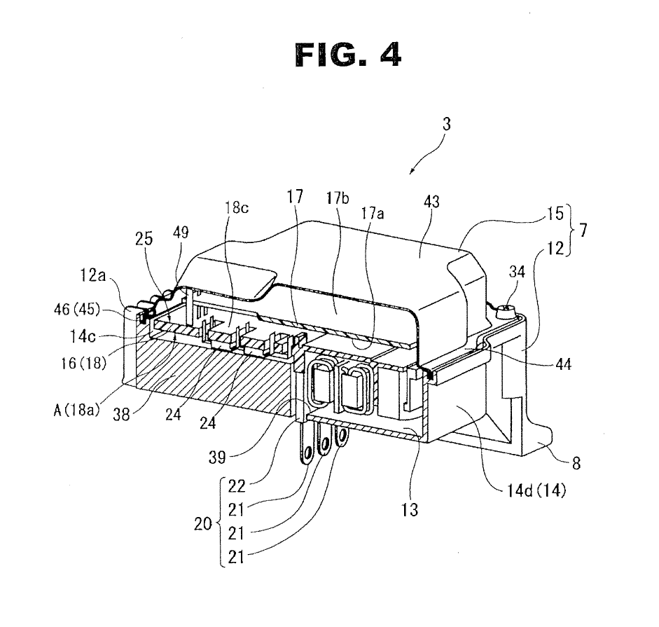

As shown in FIGS. 3 and 4, the cover 15 is formed, for instance, by press-molding a metal sheet into a substantially dished shape. The cover 15 has a swelling portion 43 that swells or expands toward a side opposite to the case 12 to accommodate the control module 17, a flange portion 44 that is formed at an outer circumferential edge of the swelling portion 43 and a protruding edge 45. The protruding edge 45 is formed by bending an outer circumferential edge of the flange portion 44 downwards (to a case 12 side). The protruding edge 45 corresponds to the convex line.

As shown in FIGS. 3 to 5, the case 12 is formed from, for instance, an aluminium alloy which has a relatively high thermal conductivity by a so-called die-casting. A first wall section 14a, which corresponds to one side of the rectangular circumferential wall 14 of the case 12, has an opening portion 36 that is formed by cutting most of the first wall section 14a from the upper side. As can be seen in FIG. 3, an external connector 19 of the power module 16 is inserted and fitted into this opening portion 36. The opening portion 36 is shaped into a shape fitting a flange section 19a that is formed at a root portion of the external connector 19, and the flange section 19a is bonded and fixed to an opening edge of the opening portion 36 through an adhesive sealing material (not shown) provided between the opening edge of the opening portion 36 and the flange section 19a.

Here, in FIGS. 3 to 5, a reference sign 12a denotes a cooling fin formed on an outer surface of the case 12.

A top edge of the circumferential wall 14 of the case 12 and an upper edge of the flange section 19a of the external connector 19 are provided with a continuous seal groove 46. The protrusion 70, for fixing the cover 15 to the case 12 at a predetermined position in the seal groove 46, is each provided on the inner wall surface in the seal groove 46 at the four side positions of the circumferential wall 14 (at positions of first to fourth wall sections 14a to 14d). Then by inserting the protruding edge 45 of the cover 15 into the seal groove 46 of the case 12, the protruding edge 45 is fitted to the predetermined position in the seal groove 46 while the movement of the protruding edge 45 in the width direction of the seal groove 46 is being limited by the protrusion 70. Further, by screwing a plurality of cover fixing screws 34 (see FIG. 3), the cover 15 and the case 12 are connected and fixed together. Here, although a sealing material is not shown in FIGS. 3 to 5, for instance, the seal groove 46 is filled with the sealing material, then a gap between the cover 15 and the case 12 can be sealed.

Four cylindrical power module supporting portions 37, protruding from respective four corner positions of the wall 13 toward the cover 15, are formed on the bottom wall 13 of the case 12. A top of each power module supporting portion 37 is provided with a screw hole 37a into which a power module fixing screw 61 is screwed.

Further, a protruding block 38, having a substantially rectangular shape and protruding from the bottom wall 13 toward the cover 15, is formed as a heat-receiving part at an area on the bottom wall 13, which corresponds to a mounting area of a switching element 24 that is provided on a power module 16 side. The protruding block 38 serves as a heat sink having a large heat capacity.

The protruding block 38 is located in the substantially middle of the case 12. More specifically, the protruding block 38 is spaced respective certain distances apart from the opposing two wall sections of the first wall section 14a and the second wall section 14b of the rectangular circumferential wall 14. Also, the protruding block 38 is spaced a certain distance apart from the fourth wall section 14d that is opposite to the third wall section 14c where the cooling fin 12a is provided. Then, the protruding block 38 is formed integrally and continuously with the third wall section 14c having the cooling fin 12a. Four corner positions on an upper surface of the protruding block 38 are provided with four screw holes 38a into which respective power module fixing screws 62 are screwed.

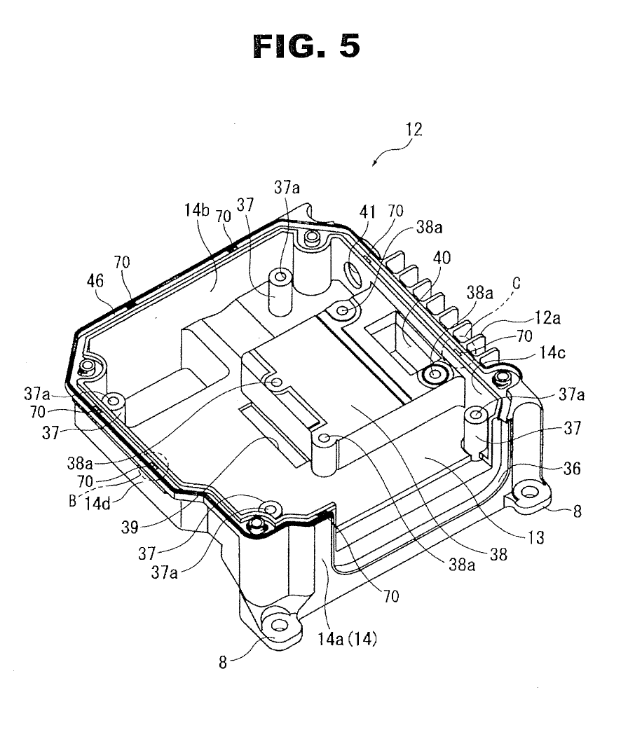

A reference sign 40 in FIGS. 3 and 5 denotes a connector insertion hole having a rectangular shape in cross section. This connector insertion hole 40 penetrates a side end portion, on a third wall section 14c side, of the protruding block 38. A reference sign 39 denotes a power supply terminal insertion hole that is formed at a corner between an end surface of the protruding block 38 on a fourth wall section 14d side and the bottom wall 13 of the case 12. Further, a reference sign 41 denotes a breathing hole. The breathing hole 41 is formed on the third wall section 14c and is positioned on a second wall section 14b side with respect to the protruding block 38. A breathing filter 42 (see FIGS. 1 and 2), which is permeable to the air but impermeable to water, is fixed to this breathing hole 41.

The power module 16 has a base plate 18 which is formed by molding using, for instance, synthetic resin material and whose surface or whose inside is provided with a plurality of metal bus bars (not shown), the external connector 19 formed integrally with or fixedly connected to one end of the base plate 18 and the above-mentioned stator connector 20 and sensor connector 23 protruding from the base plate 18 in a direction orthogonal to the base plate 18.

The base plate 18 is provided with various electronic components on a component mounting surface 18a (see FIG. 4) thereof which faces the bottom wall 13 of the case 12.

The external connector 19 corresponds to a power supply connector. The external connector 19 faces the outside through the opening portion 36 of the case 12, and receives and inputs/outputs power and signal from/to an external electronic device.

The stator connector 20 is provided in the substantially middle of the component mounting surface 18a, while the sensor connector 23 is provided at one end on the component mounting surface 18a. These stator connector 20 and sensor connector 23 have a substantially rectangular plate shape, and extend with both connectors being parallel to each other.

The stator connector 20 has three power supply terminals 21 arranged along an axial direction (an externally connecting direction) of the external connector 19 and a covering portion 22 covering a root portion of each power supply terminal 21. The covering portion 22 is formed integrally with the base plate 18 by the same resin material as that of the base plate 18 and protrudes from the component mounting surface 18a. The power supply terminals 21 are drive terminals to feed three-phase drive current to the electric motor 2.

The sensor connector 23 has the rotation position sensor connector and the temperature sensor connector with these sensor connectors arranged along the axial direction of the external connector 19, and a plurality of terminals are disposed inside the connector (there is no drawing).

Furthermore, as shown in FIG. 3, a plurality of snap-fit portions 47 are provided on a control module opposing surface 18c, which is a reverse side to the component mounting surface 18a, of the base plate 18. The snap-fit portions 47 protrude from an outer circumferential edge of the control module opposing surface 18c in the direction orthogonal to the base plate 18, and holds the control module 17 in a so-called snap-fitting manner in which the control module 17 is fitted to and held by the plurality of snap-fit portions 47. In addition, a plurality of connecting terminals 52 for electrically connecting the power module 16 and the control module 17 are provided on the control module opposing surface 18c.

The snap-fit portion 47 has a control module supporting portion 48 and a holding portion 49. Upon the assembly, the control module 17 is seated on the control module supporting portion 48, and a top end (a top nail) of the holding portion 49 is fitted onto a cover opposing surface 17b of the control module 17. With this snap-fit structure, positioning of the control module 17 is achieved, namely that the control module 17 is positioned with the control module 17 spaced by the certain distance from the base plate 18 in the direction orthogonal to the base plate 18. More specifically, as can be seen in FIG. 4, the control module 17 is located inside the cover 15, which is positioned on a cover 15 side with respect to an opening end of the case 12, and is held by each snap-fit portion 47. The control module 17 is consequently accommodated in the swelling portion 43 of the cover 15, as shown in FIG. 4.

As shown in FIG. 3, the control module 17 is formed by forming conductive patterns (not shown) on both front and back surfaces of a non-conductive resin board such as a glass epoxy resin board and mounting a number of electronic components (not shown) on the conductive patterns. The control module 17 is provided with a plurality of cutting portions 17c at positions corresponding to the respective holding portions 49 of the snap-fit portions 47 on an outer circumferential edge of the control module 17. The cutting portion 17c is shaped into a shape fitting a shape in cross-section of a fitting part of the holding portion 49. Then, the control module 17 is positioned with the control module 17 being parallel to or horizontal with respect to the base plate 18 by fitting the fitting parts of the holding portions 49 to the respective cutting portions 17c.

Further, as shown in FIG. 3, a plurality of through holes 53 are formed at positions corresponding to the respective connecting terminals 52 on the surface, on the power module 16 side, of the control module 17. The connecting terminal 52 is inserted into the through hole 53, and is electrically connected to the through hole 53 with solder. Then the control module 17 inputs information concerning the driver's braking operation and the operating condition of the vehicle through the external connector 19 and each connecting terminal 52, and outputs a drive command signal generated on the basis of this information to each switching element 24 through each connecting terminal 52, thereby driving the electric motor 2 with a switching action of each switching element 24 controlled.

<Embodiment 1 of Protrusion>

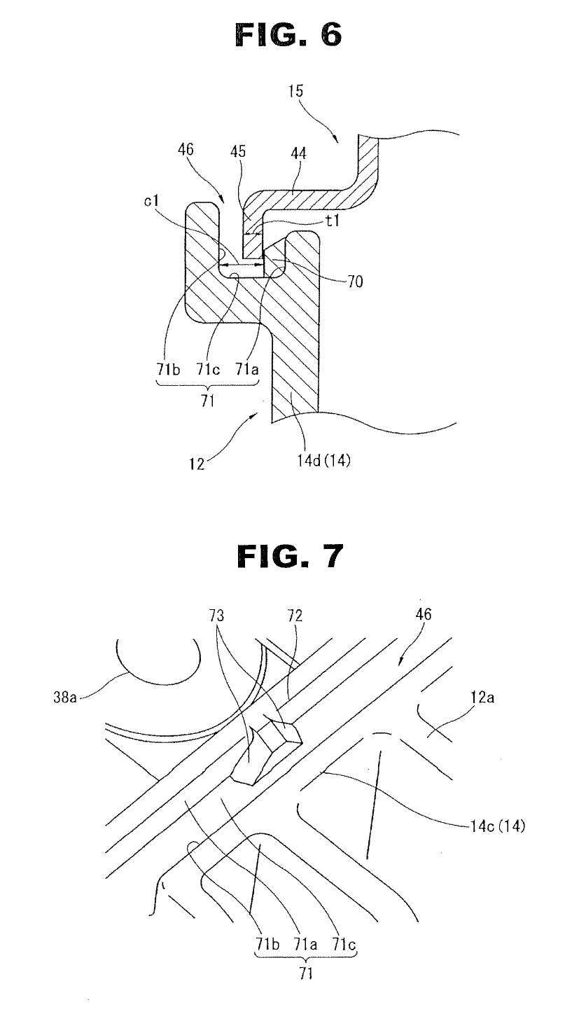

FIG. 6 is an enlarged schematic view (a sectional view when the cover 15 is fitted to the case 12) of a part (a circle B) of FIG. 5, for explaining an example of the protrusion 70. The protrusion 70 is formed on the inner circumferential surface 71a of the inner wall surface 71 (71a to 71c) in the seal groove 46 so as to protrude toward the outer circumferential surface 71b of the inner wall surface 71. A clearance c1 between the protrusion 70 and the outer circumferential surface 71b is set to be greater than a thickness t1 of the protruding edge 45 of the cover 15. With this setting, when the protruding edge 45 is inserted into the seal groove 46, the protruding edge 45 is fitted to the predetermined position in the seal groove 46 while the movement of the protruding edge 45 in the width direction of the seal groove 46 is being limited with the protruding edge 45 sandwiched between the protrusion 70 and the outer circumferential surface 71b at a position of the protrusion 70.

Here, instead of forming the protrusion 70 on the inner circumferential surface 71a side as shown in FIG. 6, the protrusion 70 can be formed on the outer circumferential surface 71b. Also in this case, the protruding edge 45 inserted into the seal groove 46 is fitted to the predetermined position in the seal groove 46 while the movement of the protruding edge 45 in the width direction of the seal groove 46 is being limited, in the same manner as the above.

<Embodiment 2 of Protrusion>

FIG. 7 is an enlarged schematic view of a part (a circle C) of FIG. 5, for explaining a modification of the embodiment 1.

The protrusion 70 is formed into a substantially pyramidal shape or frustum shape, and has tapered surfaces 73 that tilt or slope in an oblique upward direction from a bottom wall surface 71c side toward an opening 72 side of the seal groove 46.

By forming such tapered surfaces 73, as compared with the case of the embodiment 1 in which the protrusion 70 whose side surface merely extends from the bottom wall surface side of the inner wall surface toward the opening side of the seal groove is formed (i.e. an angle θ between the bottom wall surface 71c and the protrusion 70 is 90°), in a case where a sealing material such as a liquid gasket is provided around the protrusion 70 in the seal groove 46, an area around the protrusion 70 and a root portion of the protrusion 70 can be easily filled with the sealing material without any void.

<Embodiment 3 of Protrusion>

FIG. 8 is an enlarged schematic view for explaining another modification of the embodiment 1 (an modification of FIG. 6).

The protrusion 70 is formed so that a height h1 of the protrusion 70 in the depth direction of the seal groove 46 is set to be smaller than a depth d (a depth on the inner circumferential surface 71a side in FIG. 8) of the seal groove 46 also smaller than a filling height h2 of a sealing material 74, then as shown in FIG. 8, most of the protrusion 70 is buried in the sealing material 74. With this setting, as same as the embodiment 1, the movement of the protruding edge 45 in the width direction of the seal groove 46 is limited, and the creepage distance of the sealing material 74 can be adequately secured.

<Embodiment 4 of Protrusion>

FIG. 9 is an enlarged schematic view for explaining a modification of the embodiment 3.

The protrusion 70 is formed from a pair of protruding portions 75a and 75b that protrude from the bottom wall surface 71c toward the opening 72 of the seal groove 46. The protruding portions 75a and 75b are arranged with a predetermined space (a predetermined width) w1 provided between these protruding portions 75a and 75b. Further, the width w1 between the protruding portions 75a and 75b is set to be greater than the thickness t1 of the protruding edge 45 so that when the protruding edge 45 is inserted into the seal groove 46, a part (a top end) of the protruding edge 45 is fitted between the protruding portions 75a and 75b. With this setting, the protruding edge 45 inserted into the seal groove 46 is sandwiched between the protruding portions 75a and 75b. Therefore, as compared with the embodiment 1, the movement of the protruding edge 45 in the width direction of the seal groove 46 is more limited.

<Embodiment 5 of Protrusion>

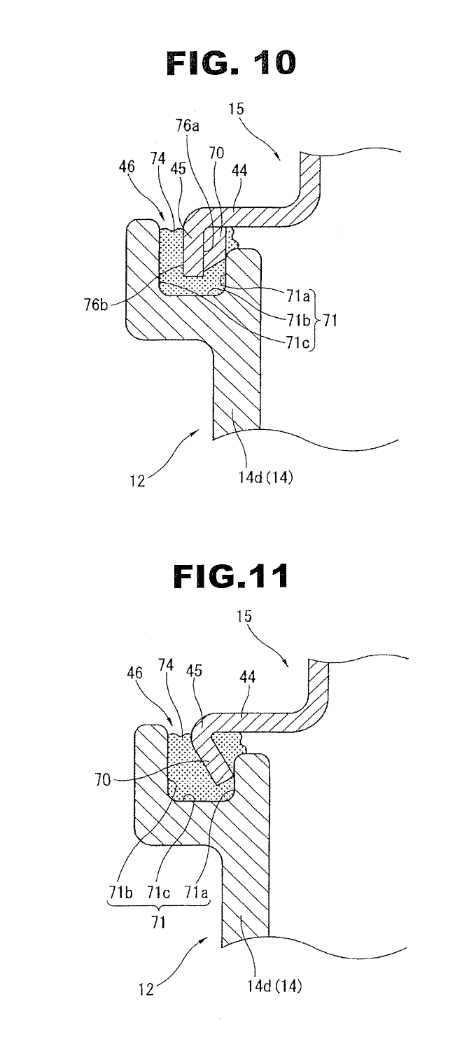

FIG. 10 is an enlarged schematic view for explaining another modification of the embodiment 3.

The protrusion 70 is formed on the opposing surface 76a, which faces the inner circumferential surface 71a of the seal groove 46, of the protruding edge 45 of the cover 15 so as to protrude toward the inner circumferential surface 71a. Also in the case where the protrusion 70 is formed on the protruding edge 45 side, as same as the embodiment 1, when the protruding edge 45 is inserted into the seal groove 46, the movement of the protruding edge 45 in the width direction of the seal groove 46 is limited.

Here, instead of forming the protrusion 70 on the opposing surface 76a facing the inner circumferential surface 71a as shown in FIG. 10, the protrusion 70 can be formed on the opposing surface 76b that faces the outer circumferential surface 71b. Also in this case, the protruding edge 45 inserted into the seal groove 46 is fitted to the predetermined position in the seal groove 46 while the movement of the protruding edge 45 in the width direction of the seal groove 46 is being limited, in the same manner as the above.

<Embodiment 6 of Protrusion>

FIG. 11 is an enlarged schematic view for explaining a modification of the embodiment 5.

The protrusion 70 is formed by bending a part of the protruding edge 45 of the cover 15 in a direction of the inner circumferential surface 71a (in FIG. 11, the protruding edge 45 is bent from a root portion of the protruding edge 45). Also in this case, as same as the case of the embodiment 5, when the protruding edge 45 is inserted into the seal groove 46, the movement of the protruding edge 45 in the width direction of the seal groove 46 is limited.

Here, in the case of the embodiment 5, the cover 15 formed by, for instance, aluminium die-casting is used. However, in the case where the protrusion 70 is formed by the bending process as shown in FIG. 6, the cover 15 formed by sheet-metal working could be used.

<Embodiment 7 of Protrusion>

With respect to the arrangement of the protrusion 70, a plurality of protrusions 70 can be separately arranged at the four side positions of the circumferential wall 14 (at positions of the first to fourth wall sections 14a to 14d).

In addition, a part of, at least one side seal groove 46 (or at least one side protruding edge 45) of the four sides has the shape extending straight, like the second to fourth wall sections 14b to 14d in FIG. 5, and two protrusions 70 or more could be provided at this straight part of the one side seal groove 46 (or of the one side protruding edge 45 that is fitted into the one side seal groove 46). Then, the remaining three side seal grooves 46 (or the remaining three side protruding edges 45) of the four sides could be provided with one protrusion 70 or more, like the first wall section 14a in FIG. 5. With this structure, even when the case 12 and the cover 15 relatively rotate with respect to the extending direction of the seal groove 46, by the two protrusions 70 or more provided at the straight part of the seal groove 46 (or at the straight part of the protruding edge 45), the rotation movement with respect to the extending direction of the seal groove 46 is limited.

Furthermore, in order to facilitate the limitation of the rotation movement of the case 12 and the cover 15 with respect to the extending direction of the seal groove 46, for instance, as shown in FIG. 7, the protrusion 70 provided in the seal groove 46 could be formed into a shape extending in the extending direction of the seal groove 46 so as to have a long length.

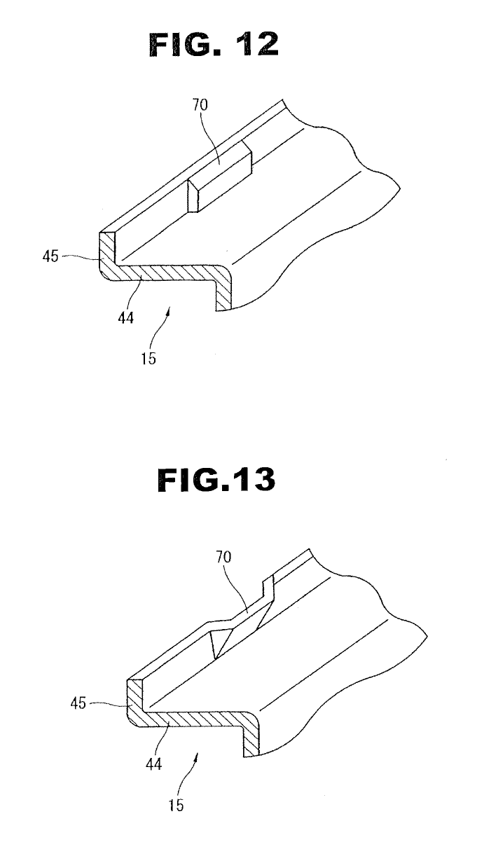

Or alternatively, for instance, as shown in FIGS. 12 and 13, the protrusion 70 provided at the protruding edge 45 could be formed into a shape extending in an extending direction of the protruding edge 45 (which is the same as the extending direction of the seal groove 46) so as to have a long length.

The present invention has been explained on the basis of the above embodiments using the drawings of the structure or configuration in which, for instance, the protrusion 70 is provided on the inner circumferential surface 71a side in the seal groove 46 and the protrusion 70 is provided on the protruding edge 45 side which faces the inner circumferential surface 71a. However, also in the case of the structure in which the protrusion 70 is provided on the outer circumferential surface 71b side in the seal groove 46 and the protrusion 70 is provided on the protruding edge 45 side which faces the outer circumferential surface 71b, when the protruding edge 45 is inserted into the seal groove 46, the movement of the protruding edge 45 in the width direction of the seal groove 46 is limited, and the positioning shift can be suppressed and the workability of the assembly can be improved.

From the foregoing, the present invention includes the following structure or configuration of the electronic control device, and has the following effects.

In the electronic control device, the protrusion is formed in the seal groove, and has a tapered surface that tilts in an oblique upward direction from a bottom wall surface toward an opening of the seal groove.

In the electronic control device, the protrusion is buried in the sealant.

In the electronic control device, the protrusion is formed from a pair of protruding portions that protrude from a bottom wall surface toward an opening of the seal groove, and the protruding portions are arranged with a predetermined space provided between these protruding portions.

The entire contents of Japanese Patent Application No. 2012-208814 filed on Sep. 21, 2012 are incorporated herein by reference.

Although the invention has been described above by reference to certain embodiments of the invention, the invention is not limited to the embodiments described above. Modifications and variations of the embodiments described above will occur to those skilled in the art in light of the above teachings. The scope of the invention is defined with reference to the following claims.

What is claimed is:

1. An electronic control device having a circuit board on which electronic components are mounted, the electronic control device comprising:
an enclosure formed from a plurality of enclosure members and accommodating the circuit board in a space inside the enclosure, the enclosure having
(a) a first enclosure member which is provided at a connecting part thereof with a seal groove; and
(b) a second enclosure member which is provided at a connecting part thereof with a convex line that is fitted into the seal groove of the first enclosure member, and
the first and second enclosure members being connected together to form the enclosure; and
a protrusion formed on either one of an inner wall surface in the seal groove or an opposing surface, which faces the inner wall surface of the seal groove, of the convex line so as to protrude toward the other surface, the protrusion limiting a movement, in a seal groove width direction, of the convex line fitted into the seal groove, and
the seal groove and the convex line being sealed with a sealant.

2. The electronic control device as claimed in claim 1, wherein:
the protrusion is formed on either one of an inner circumferential surface of the inner wall surface in the seal groove or an opposing surface, which faces the inner circumferential surface of the seal groove, of the convex line.

3. The electronic control device as claimed in claim 1, wherein:
the first enclosure member has a four-side-surrounding circumferential wall, and the seal groove is provided at a top edge of the circumferential wall,
a part of, at least one side seal groove of the four sides has a shape extending straight,
two protrusions or more are provided at either one of the straight part of the one side seal groove or the convex line that is fitted into the straight part of the one side seal groove, and
one protrusion or more is provided at either one of the remaining three side seal grooves of the four sides or the convex lines that are fitted into the remaining three side seal grooves.

4. The electronic control device as claimed in claim 1, wherein:
the protrusion is formed in the seal groove, and has a tapered surface that tilts in an oblique upward direction from a bottom wall surface toward an opening of the seal groove.

5. The electronic control device as claimed in claim 1, wherein:
the protrusion is buried in the sealant.

6. The electronic control device as claimed in claim 1, wherein:
the protrusion is formed from a pair of protruding portions that protrude from a bottom wall surface toward an opening of the seal groove, and
the protruding portions are arranged with a predetermined space provided between these protruding portions.
